(19) United States
(12) Patent Application Publication
(10) Pub. No.: US 2014/0111944 A1
(43) Pub. Date: Apr. 24, 2014

(54) HEAT DISSIPATION STRUCTURE FOR MULTILAYER BOARD AND METHOD OF MANUFACTURING THE STRUCTURE

(71) Applicant: DENSO CORPORATION, KARIYA-CITY (JP)

(72) Inventors: Yoshimichi HARA, Kuwana-city (JP); Toshihisa YAMAMOTO, Anjo-city (JP); Takahiro YAMANAKA, Kariya-city (JP); Kouji KAMEYAMA, Kariya-city (JP); Yuuji KOBAYASHI, Nukata-gun (JP)

(73) Assignee: DENSO CORPORATION, KARIYA-CITY (JP)

(21) Appl. No.: 14/059,809

(22) Filed: Oct. 22, 2013

(30) Foreign Application Priority Data
Oct. 23, 2012 (JP) 2012-233795

(51) Int. Cl. H05K 7/20; H05K 3/00

(52) U.S. Cl. CPC H05K 7/2039; H05K 3/0011
USPC 361/720; 29/887

(57) ABSTRACT

A heat dissipation structure includes a multilayer board and a heat dissipator for dissipating heat generated in an electronic device incorporated in the multilayer board. The multilayer board has multiple base portions layered together and made of electrically insulating material. The base portion located between the electronic device and the heat dissipator has no interlayer connection conductor made of electrically conducting material and serves as an electrically insulating layer for providing electrical isolation between the electronic device and the heat dissipator.

### CROSS REFERENCE TO RELATED APPLICATION

This application is based on Japanese Patent Application No. 2012-233795 filed on Oct. 23, 2012, the contents of which are incorporated herein by reference.

### FIELD

The present disclosure relates to a heat dissipation structure having a multilayer board and a heat dissipator and also relates to a method of manufacturing the heat dissipation structure.

### BACKGROUND

JP-A-2004-158545 discloses a multilayer board for efficiently dissipating heat of a semiconductor device at low cost. The multilayer board has a heat dissipation plate on both sides, and the heat dissipation plate is isolated from the semiconductor device.

### SUMMARY

In a heat dissipation structure for a semiconductor device (e.g., MOSFET) of a motor drive circuit, a surface-mount device (SMD) is mounted on a front side of a board, and a heat dissipator is in contact with a back side of the board to dissipate heat. Disadvantages of this structure are that devices cannot be mounted on the back side of the board and that heat dissipation efficiency is degraded due to the fact that heat is dissipated through the board.

To overcome the disadvantages, a surface-mount device with a heat dissipation surface may be mounted on the back side of the board, and the heat dissipator may be placed in contact with the heat dissipation surface of the surface-mount device through a heat conductor. However, when multiple surface-mount devices are mounted on the back side of the board, the thicknesses of the surface-mount devices from the back side of the board may be different from each other. In such a case, the heat conductors need to have different thicknesses to form a flat surface where the heat dissipator is mounted. Further, since the heat dissipator generally has electrical conductivity, the heat conductors need to provide electrical isolation between the heat dissipator and the surface-mount devices. Therefore, there is a need to design by taking into consideration not only heat dissipation through the thickest heat conductor but also electrical isolation through the thinnest heat conductor. This may result in use of a high-performance heat conductor, which is generally expensive.

The multilayer board disclosed in JP-A-2004-158545 can face a similar issue to that discussed above.

In view of the above, it is an object of the present disclosure to provide a heat dissipation structure for a multilayer board and a method of manufacturing the heat dissipation structure for improving heat dissipation efficiency by thinning or removing a heat conductor.

According to a first aspect of the present disclosure, a heat dissipation structure includes a multilayer board and a heat dissipator.

The multilayer board has a first surface and a second surface opposite to the first surface in a layered direction. The heat dissipator is located on the first surface side of the multilayer board. The multilayer board includes an electronic device, an electrically insulating layer, and multiple base portions made of electrically insulating material. The electronic device is incorporated in at least one of the base portions. The insulating layer and the base portions are layered together to form the multilayer board in such a manner that a first one of the base portions defines the first surface of the multilayer board and that the insulating layer defines the second surface of the multilayer board. Each of the base portions has an interlayer connection conductor extending therethrough in the layered direction. The interlayer connection conductor is made of electrically conducting material and connected to the electronic device. At least one of the base portions has a conductive pattern connected to the interlayer connection conductor. The insulating layer has no interlayer connection conductor and is located between the electronic device and the heat dissipator in the layered direction.

According to a second aspect of the present disclosure, a method of manufacturing a heat dissipation structure for a multilayer board includes a preparing step, an incorporating step, a layering step, an applying step, and a mounting step. The preparing step includes preparing an electrically insulating layer and multiple base portions made of electrically insulating material. The preparing step further includes forming a via hole in each of the base portions and filling the via hole with electrically conducting material. The preparing step further includes forming a conductive pattern on at least one of the base portions. The incorporating step includes incorporating an electronic device in the base portions. The layering step includes layering the insulating layer and the base portions together in a layered direction to form a layered structure such that an outermost surface of the layered structure is defined by the insulating layer and such that the at least one of the base portions is located between the electronic device and the insulating layer. The applying step includes applying heat and pressure to the layered structure by using a pressing machine so that the insulating layer and the base portions are bonded together into the multilayer board. The mounting step includes mounting a heat dissipator on the insulating layer side of the multilayer board.

According to a third aspect of the present disclosure, a method of manufacturing a heat dissipation structure for a multilayer board includes a preparing step, an incorporating step, a layering step, an arranging step, and an applying step. The preparing step includes preparing an electrically insulating layer and multiple base portions made of electrically insulating material. The preparing step further includes forming a via hole in each of the base portions and filling the via hole with electrically conducting material. The preparing step further includes forming a conductive pattern on at least one of the base portions. The incorporating step includes incorporating an electronic device in the base portions. The layering step includes layering the insulating layer and the base portions together in a layered direction to form a layered structure such that an outermost surface of the layered structure is defined by the insulating layer and such that the at least one of the base portions is located between the electronic device and the insulating layer. The arranging step includes arranging the layered structure between a circuit board and a heat dissipator in the layered direction in such a manner that the heat dissipator is located on the insulating layer side of the layered structure. The applying step includes applying heat and pressure to the layered structure through the circuit board and the heat dissipator by using a pressing machine.

### BRIEF DESCRIPTION OF THE DRAWINGS

The above and other objects, features, and advantages will become more apparent from the following description and drawings. In the drawings:

FIG. 1 is a diagram illustrating a cross-sectional view of a heat dissipation structure for a multilayer board according to a first embodiment of the present disclosure;

FIG. 2 is a diagram illustrating a drive circuit provided by the multilayer board;

FIG. 3 is a diagram illustrating a base-portion forming process according to the first embodiment;

FIG. 4 is a diagram illustrating a layering process according to the first embodiment;

FIG. 5 is a diagram illustrating a first procedure of a heat and pressure applying process according to the first embodiment;

FIG. 6 is a diagram illustrating a second procedure of the heat and pressure applying process according to the first embodiment;

FIG. 7 is a diagram illustrating a heat-dissipator mounting process according to the first embodiment;

FIG. 8 is a diagram illustrating a heat-dissipator bonding process according to a second embodiment of the present disclosure;

FIG. 9 is a diagram illustrating a cross-sectional view of a heat dissipation structure for a multilayer board according to a third embodiment of the present disclosure;

FIG. 10 is a diagram illustrating a layering process according to the third embodiment;

FIG. 11 is a diagram illustrating a heat and pressure applying process according to the third embodiment;

FIG. 12 is a diagram illustrating a cross-sectional view of a heat dissipation structure for a multilayer board according to a modification of the third embodiment;

FIG. 13 is a diagram illustrating a cross-sectional view of a heat dissipation structure for a multilayer board according to a modification of the first embodiment; and

FIG. 14 is a diagram illustrating a cross-sectional view of a heat dissipation structure for a multilayer board according to another modification of the third embodiment.

### DETAILED DESCRIPTION

Embodiments of the present disclosure are described below with reference to the drawings in which like reference numerals depict like elements. Throughout the embodiments, “connected” means “electrically connected” unless explicitly stated otherwise.

### First Embodiment

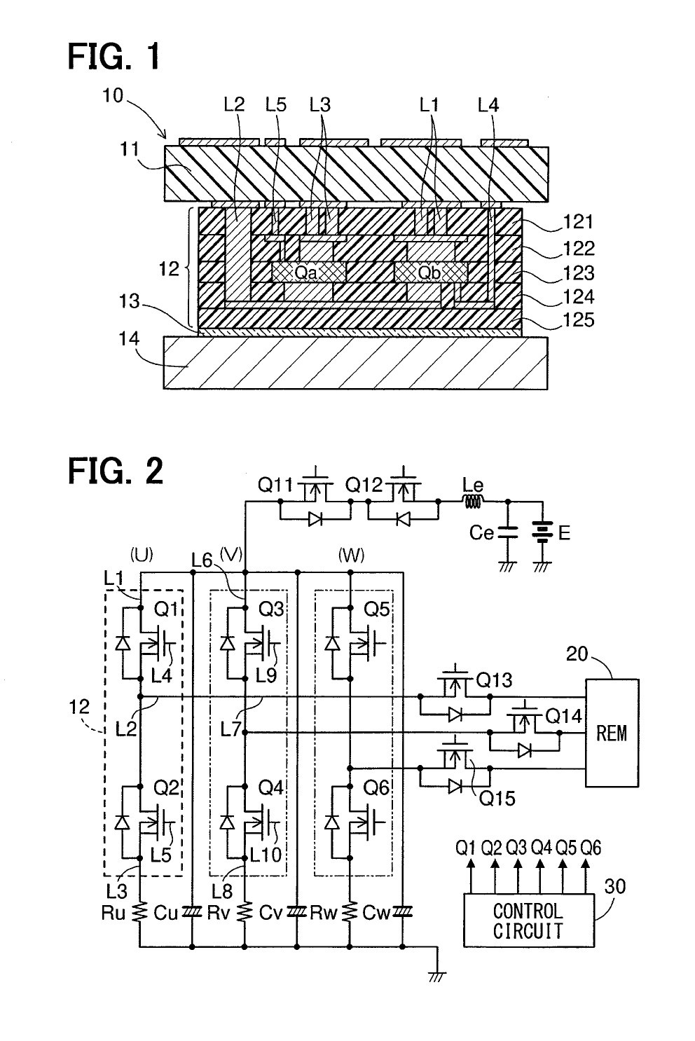

A heat dissipation structure 10 according to a first embodiment of the present disclosure is described below with reference to FIGS. 1-7. As shown in FIG. 1, the heat dissipation structure 10 includes a circuit board 11, a multilayer board 12, a heat conductor 13, and a heat dissipator 14.

The circuit board 11 has conductive patterns and electronic components connected to the conductive patterns. According to the first embodiment, the circuit board 11 is configured to control a three-phase (e.g., U-phase, V-phase, and W-phase) rotating electrical machine 20 shown in FIG. 2. For example, the circuit board 11 includes a control circuit 30, resistors Ru, Rv, and Rw, capacitors Cu, Cv, and Cw, semiconductor devices Q1, Q2, Q3, Q4, Q5, and Q6, and semiconductor devices Q11, Q12, Q13, Q14, and Q15. It is noted that at least one of the semiconductor devices Q1-Q6 as electronic devices is incorporated in the multilayer board 12. According to the first embodiment, the semiconductor devices Q1 and Q2 are incorporated in the multilayer board 12 and labeled as “Qa” and “Qb” in FIG. 1, respectively. The semiconductor devices Q1 and Q2 are hereinafter sometimes referred to as the “semiconductor devices Qa and Qb”, respectively.

The rotating electrical machine 20 is a machine having a rotating portion (e.g., shaft). An example of the rotating electrical machine 20 can include a generator, a motor, and an alternator. The control circuit 30 sends drive signals (e.g., pulse-width modulation signals) to the semiconductor devices Q1-Q6 to control ON and OFF operations of the semiconductor devices Q1-Q6. Because of this control, electrical power supplied from an electrical power source E through a filter circuit constructed with a coil Le and a capacitor Ce is converted and outputted to the rotating electrical machine 20. For example, the power source E can be a battery (in particular, secondary cell) or a fuel cell. When the power source E is a secondary cell, power regenerated in the rotating electrical machine 20 can be stored in the power source E through a diode.

The multilayer board 12 has base portions, conductive patterns, and interlayer connection conductors that are joined together under heat and pressure. According to the first embodiment, the multilayer board 12 has five base portions 121, 122, 123, 124, and 125 that are layered on top of each other. Each of the base portions 121, 122, 123, 124, and 125 is made of electrically insulating material (e.g., thermoplastic resin). Each of the base portions 121, 122, 123, 124, and 125 can have any thickness. For example, some or all of the base portions 121, 122, 123, 124, and 125 can have the same thickness. Alternatively, some or all of the base portions 121, 122, 123, 124, and 125 can have different thicknesses. Further, at least one of the base portions 121, 122, 123, 124, and 125 can have a multi-layer structure formed with thinner base portions layered on top of each other. Examples of the multilayer board 12 can include a printed wiring board and a PALAP (patterned prepreg lay up process) board and. “PALAP” is a registered trademark of DENSO Corporation.

As shown in FIG. 1, the semiconductor devices Qa and Qb are accommodated in the base portion 123. An initial thickness of the base portion 123 is set so that the thickness of the base portion 123 can be substantially equal to the thickness of the semiconductor devices Qa and Qb after a heat and pressure application process. The “substantially equal to” covers a manufacturing tolerance associated with the heat and pressure application process.

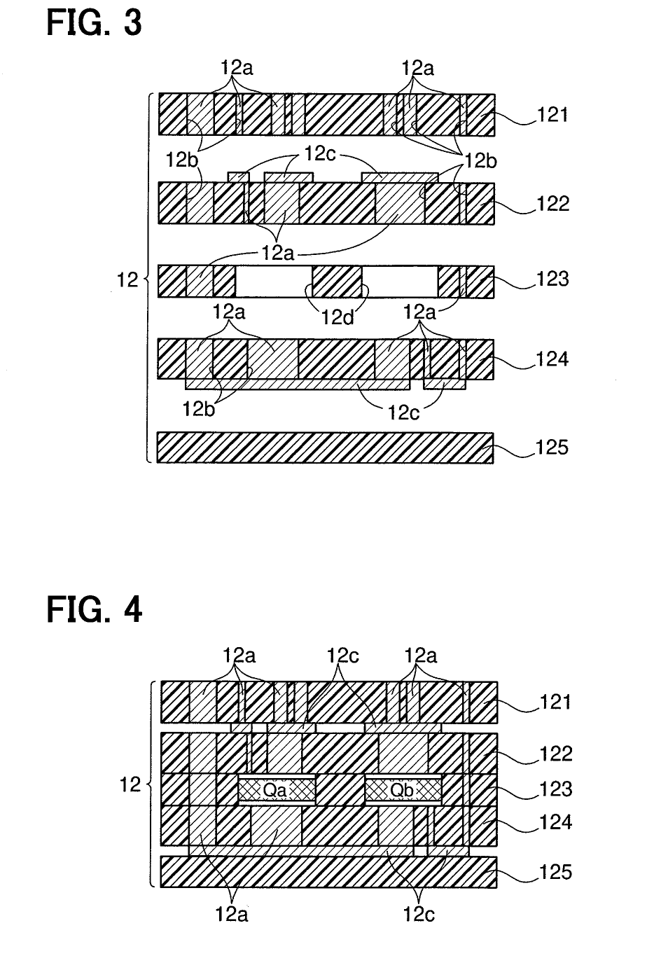

As shown in FIG. 3, each of the base portions 121, 122, 123, and 124 has a via hole 12b filled with an electrically conducting material 12a. Further, each of the base portions 122 and 124 has a conductive pattern 12c made of electrically conducting material. It is noted that the base portion 125 has no via hole 12b filled with the conducting material 12a. When the base portions 121, 122, 123, 124, and 125 are bonded together by the heat and pressure application process, the conducting materials 12a and the conducive patterns 12c are connected together to form interlayer connection conductors L1, L2, L3, L4, and L5.

The circuit board 11 and the multilayer board 12 form a drive circuit for driving the rotating electrical machine 20. As indicated by a broken line in FIG. 2, the multilayer board 12 provides a part of the drive circuit corresponding to one phase (i.e., U-phase) of the rotating electrical machine 20. As mentioned previously, the semiconductor devices Q1 and Q2 are incorporated in the multilayer board 12. For example, according to the first embodiment, the semiconductor devices Q1 and Q2 are MOSFETs. A flyback diode (i.e., freewheeling diode) is connected in parallel between an input terminal (i.e., drain) and an output terminal (i.e., source) of each of the semiconductor devices Q1 and Q2. For example, the diode can be a parasitic diode of each of the semiconductor devices Q1 and Q2. Alternatively, the diode can be a separate diode and then connected to each of the semiconductor devices Q1 and Q2.

The heat conductor 13 is interposed between the multilayer board 12 (specifically, the base portion 125) and the heat dissipator 14. The heat conductor 13 reduces thermal resistance by filling a slight gap at an interface between the multilayer board 12 and the heat dissipator 14. According to the first embodiment, the heat conductor 13 is made of heat conductive gel. Alternatively, the heat conductor 13 can be made of heat conductive grease, heat conductive adhesive, heat conductive sheet, or the like. As a distance between the multilayer board 12 and the heat dissipator 14 is smaller, the thermal resistance becomes smaller. In other words, as the thickness of the heat conductor 13 is smaller, the thermal resistance becomes smaller. Therefore, it is preferable that the thickness of the heat conductor 13 be as small as possible. The heat dissipator 14 dissipates heat to outside. For example, the heat dissipator 14 can be a heat dissipation plate, a heat dissipation fin, or the like. The heat dissipator 14 can be used as a heat conductor to exchange heat with an external device such as a cooler or a heater (not shown).

Next, a method of manufacturing the heat dissipation structure 10 is described below with reference to FIGS. 3-7. The method includes a base-portion forming process, a layering process, the heat and pressure application process, and a heat-dissipator mounting process.

(Base-Portion Forming Process)

In the base-portion forming process, the base portions 121-125 are formed as shown in FIG. 3. The conductive pattern 12c is formed on one side or both sides of some or all of the base portions 121-124, and the via hole 12b is formed at a predetermined position of each of the base portions 121-124. Each via hole 12b is filled with the conducting material 12a. Further, an accommodation hole 12d is formed in the base portion 123.

In an example of FIG. 3, the base portion 121 has the via hole 12b filled with the conducting material 12a, but does not have the conductive pattern 12c. Each of the base portions 122 and 124 has both the conductive pattern 12c and the via hole 12b filled with the conducting material 12a. The size of the conductive pattern 12c formed on the base portion 124 can be increased to improve heat dissipation efficiency. The size and number of the via holes 12b can be different between the base portions 121-124. Also, the position at which the via hole 12b is formed can be different between the base portions 121-124. Alternatively, the size, the number, and the position of the via holes 12b can be the same between some or all of the base portions 121-124. Unlike the base portions 121-124, the base portion 125 does not have either the conductive pattern 12c or the via hole 12b filled with the conducting material 12a. Therefore, the base portion 125 serves as an electrically insulating layer.

(Layering Process)

Then, in the layering process, as shown in FIG. 4, the semiconductor devices Qa and Qb are placed in the accommodation holes 12d of the base portion 123. Alternatively, the semiconductor devices Qa and Qb can be placed in the accommodation holes 12d of the base portion 123 in the base-portion forming process in advance of the layering process. Then, the base portions 121, 122, 123, 124, and 125 are layered on top of each other in this order to form a layered structure.

(Heat and Pressure Application Process)

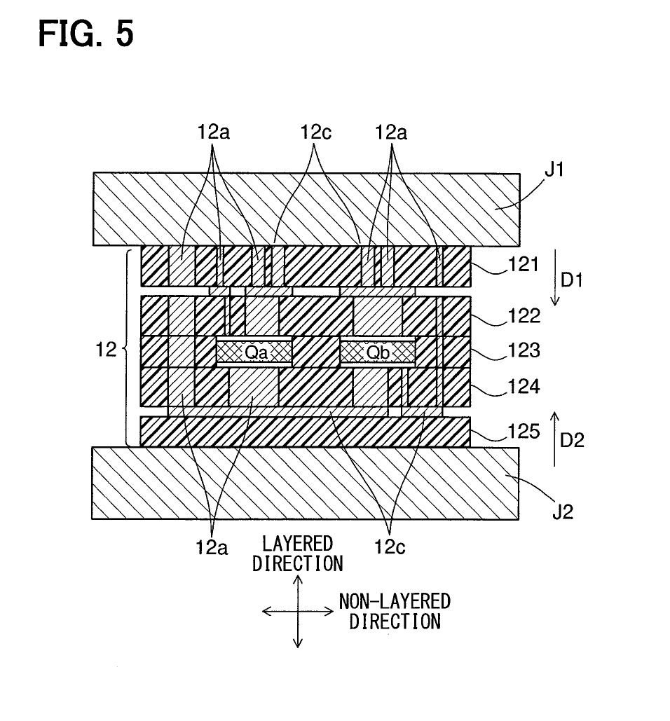

Then, the heat and pressure application process are performed. The heat and pressure application process includes a first procedure and a second procedure. In the first procedure, as shown in FIG. 5, heat and pressure are applied to the layered structure by using jigs J1 and J2 of a pressing machine. In an example of FIG. 5, the layered structure is placed between the jigs J1 and J2, and then the jigs J1 and J2 are respectively moved in directions D1 and D2 to apply heat and pressure to the layered structure. The directions D1 and D2 are opposite to each other in a layered direction of the layered structure. Alternatively, heat and pressure can be applied to the layered structure by moving one of the jigs J1 and J2 in a direction toward the other of the jigs J1 and J2 while fixing the other of the jigs J1 and J2. The application of heat and pressure to the layered structure causes the base portions 121-125 to be bonded together and also causes the conducting materials 12a, the conductive patterns 12c, and the semiconductor devices Qa and Qb to be connected together to form the interlayer connection conductors L1-L5 shown in FIGS. 1 and 2. Thus, in the first process of the heat and pressure application process, the layered structure is formed into the multilayer board 12. The multilayer board 12 has a first surface defined by the base portion 125 and a second surface defined by the base portion 121.

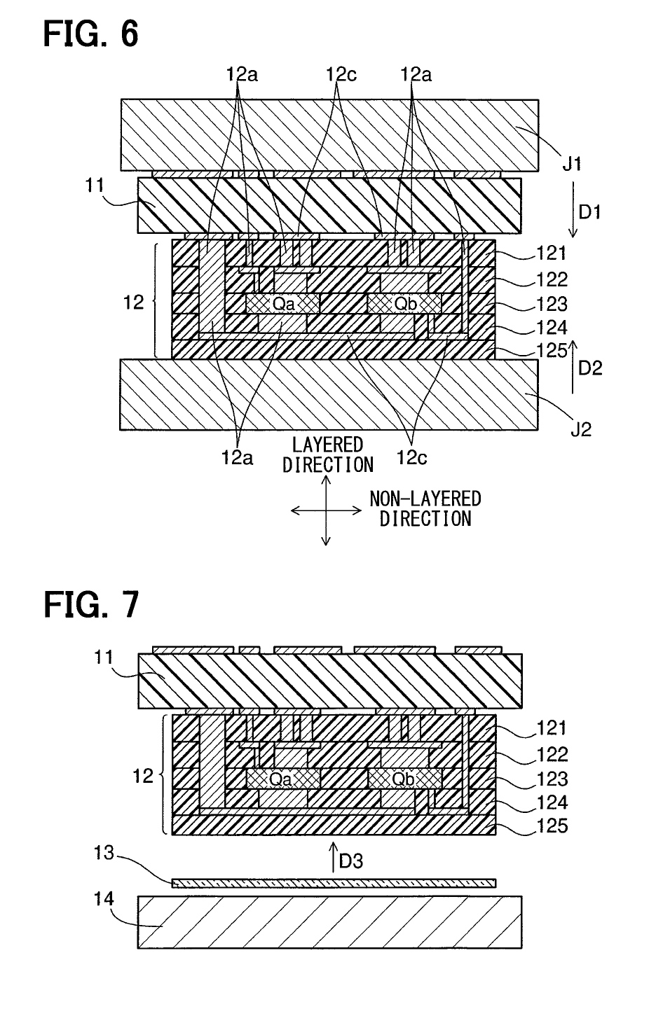

In the second procedure of the heat and pressure application process, as shown in FIG. 6, the circuit board 11 is placed on the first surface of the multilayer board 12. Then, heat and pressure are applied to the circuit board 11 and the multilayer board 12 by using the jigs J1 and J2. In an example of FIG. 6, the circuit board 11 and the multilayer board 12 are placed between the jigs J1 and J2, and then the jigs J1 and J2 are respectively moved in the opposite directions D1 and D2 to apply heat and pressure to the circuit board 11 and the multilayer board 12. Alternatively, heat and pressure can be applied to the circuit board 11 and the multilayer board 12 by moving one of the jigs J1 and J2 in a direction toward the other of the jigs J1 and J2 while fixing the other of the jigs J1 and J2. The application of heat and pressure to the circuit board 11 and the multilayer board 12 causes the conductive patterns on the circuit board 11 to be connected to the interlayer connection conductors L1-L5 and the conductive patterns 12c of the multilayer board 12. Thus, in the second process of the heat and pressure application process, the circuit board 11 and the multilayer board 12 are joined together.

(Heat-Dissipator Mounting Process)

Then, in the heat-dissipator mounting process, as shown in FIG. 7, the heat dissipator 14 is mounted on the first surface of the multilayer board 12. Specifically, as indicated by an arrow D3, the heat conductor 13 is interposed between the heat dissipator 14 and the first surface of the multilayer board 12 in the layered direction. As mentioned previously, it is preferable that the thickness of the heat conductor 13 be as small as possible to reduce the thermal resistance.

Next, advantages of the first embodiment are described.

In the heat dissipation structure 10, the semiconductor devices Qa and Qb are incorporated in the multilayer board 12 in such a manner that the base portion 125 of the multilayer board 12 is interposed between the heat dissipator 14 and the semiconductor devices Qa and Qb. Since the base portion 125 has no interlayer connection conductor, the base portion 125 serves as an electrically insulating layer to provide electrical isolation between the heat dissipator 14 and the semiconductor devices Qa and Qb. Since the base portion 125 serves as an electrically insulating layer, the distance between the multilayer board 12 and the heat dissipator 14 can be reduced (i.e., the thickness of the heat conductor 13 interposed between the multilayer board 12 and the heat dissipator 14 can be reduced). Accordingly, the thermal resistance can be reduced, and the heat dissipation efficiency can be improved.

As shown in FIGS. 1, and 3-6, the base portion 124 adjacent to the base portion 125 has the conductive pattern 12c on the near side to the heat dissipator 14. Thus, heat generated by the semiconductor devices Qa and Qb is easily transmitted to the heat dissipator 14 through the conductive pattern 12c of the base portion 124, the base portion 125, and the heat conductor 13. Therefore, the heat dissipation efficiency can be improved. The heat dissipation efficiency can be further improved by increasing the area of the conductive pattern 12c of the base portion 124.

The semiconductor devices Qa and Qb are accommodated in the accommodation holes 12d of the base portion 123 of the multilayer board 12. Thus, the semiconductor devices Qa and Qb can be protected from damage during the heat and pressure application process. In the first embodiment, the accommodation holes 12d are formed in the same base portion (i.e., the base portion 123) of the multilayer board 12. Alternatively, the accommodation holes 12d can be formed in different base portions of the multilayer board 12 so that the semiconductor devices Qa and Qb can be incorporated in different base portions of the multilayer board 12.

The initial thickness of the base portion 123 is set so that the thickness of the base portion 123 can be substantially equal to the thickness of the semiconductor devices Qa and Qb after the heat and pressure application process. Thus, there is no need to form the accommodation hole 12d in the other base portions, so that manufacturing cost can be reduced. Alternatively, the initial thickness of the base portion 123 can be set so that the thickness of the base portion 123 can be smaller than the thickness of the semiconductor devices Qa and Qb after the heat and pressure application process. In this case, another accommodation hole 12d is formed in the base portion adjacent to the base portion 123 in such a manner that the accommodation holes 12d can communicate with each other to form a single large accommodation hole 12d where each of the semiconductor devices Qa and Qb is accommodated.

The method of manufacturing the heat dissipation structure 10 includes the base-portion forming process, the layering process, the heat and pressure application process, and the heat-dissipator mounting process. In the base-portion forming process, the conductive pattern 12c is formed on one side or both sides of some or all of the base portions 121-124, and the via hole 12b is formed at the predetermined position of each of the base portions 121-124. Each via hole 12b is filled with the conducting material 12a. Then, in the layering process, the base portions 121-125 are layered on top of each other in this order to form the layer structure. The base portion 123 incorporates the semiconductor devices Qa and Qb therein. The base portion 124 is located between the base portions 123 and 125 and has the conductive pattern 12c on the near side to the base portion 125. The base portion 125 does not have either the conductive pattern 12c or the via hole 12b filled with the conducting material 12a. Then, in the heat and pressure application process, heat and pressure are applied to the layered structure by using the pressing machine so that the base portions 121-125 can be bonded together into the multilayer board 12. Then, in the heat-dissipator mounting process, the heat dissipator 14 is mounted on one side (i.e., the first surface defined by the base portion 125) of the multilayer board 12 through the heat conductor 13. Thus, in the heat dissipation structure 10 manufactured by the method according to the first embodiment, the base portion 125 serving as an electrically insulation layer can be interposed between the heat conductor 13 and the semiconductor devices Qa and Qb. Therefore, the heat dissipation efficiency can be improved by reducing the thickness of the heat conductor 13 so that the distance between the multilayer board 12 and the heat dissipator 14 can be reduced.

In the heat and pressure application process, after the circuit board 11 is stacked on the multilayer board 12 in the layered direction, heat and pressure are applied to the circuit board 11 and the multilayer board 12 by using the pressing machine. Thus, the circuit board 11 and the multilayer board 12 can be surely connected together.

### Second Embodiment

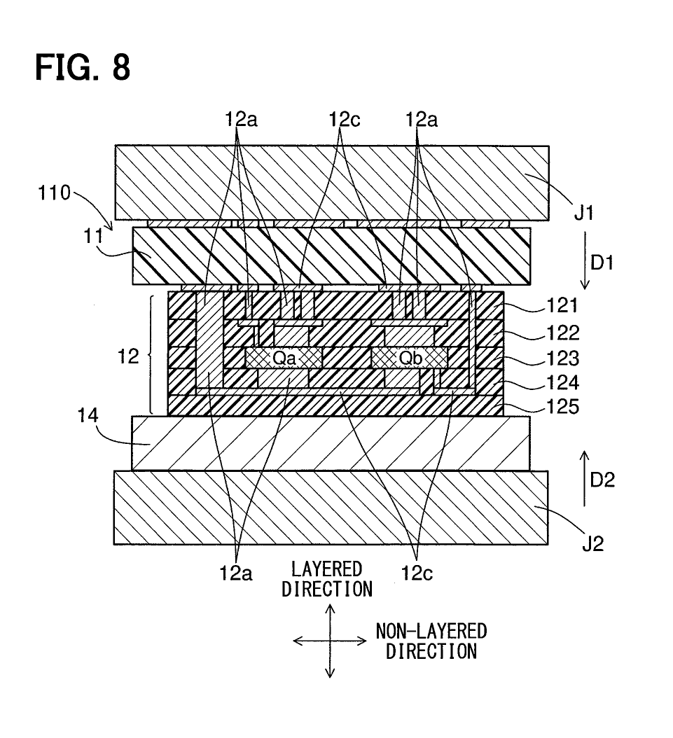

A heat dissipation structure 110 according to a second embodiment of the present disclosure is described below with reference to FIG. 8. A difference between the first embodiment and the second embodiment is as follows.

In the heat dissipation structure 10 according to the first embodiment, the heat dissipator 14 is mounted on the base portion 125 of the multilayer board 12 through the heat conductor 13. In contrast, in the heat dissipation structure 110 according to the second embodiment, the heat dissipator 14 is directly mounted on the base portion 125 of the multilayer board 12 without the heat conductor 13 so that the heat dissipator 14 can be in contact with the base portion 125.

A method of manufacturing the heat dissipation structure 110 includes the base-portion forming process, the layering process, the first procedure of the heat and pressure application process, and a heat-dissipator bonding process. That is, in the second embodiment, the second procedure of the heat and pressure application process is not performed, and the heat-dissipator bonding process is performed instead of the heat-dissipator mounting process. The heat-dissipator bonding process is described below.

(Heat-Dissipator Bonding Process)

In the heat-dissipator bonding process, as shown in FIG. 8, the circuit board 11 is placed on the second surface (i.e., the base portion 121) of the multilayer board 12, and the heat dissipator 14 is placed on the first surface (i.e., the base portion 125) of the multilayer board 12. Then, heat and pressure are applied to the circuit board 11, the multilayer board 12, and the heat dissipator 14 by using the jigs J1 and J2 of the pressing machine. During the heat-dissipator bonding process, an interface of the base portion 125 with the heat dissipator 14 is melt and pressed against the heat dissipator 14 so that the base portion 125 and the heat dissipator 14 can be bonded together. Thus, the heat dissipation structure 110 can be manufactured.

The second embodiment can have almost the same advantages as described above for the first embodiment. Further, the second embodiment can have the following advantage.

The method of manufacturing the heat dissipation structure 110 includes the base-portion forming process, the layering process, the heat and pressure application process, and the heat-dissipator bonding process. In the base-portion forming process, the conductive pattern 12c is formed on one side or both sides of some or all of the base portions 121-124, and the via hole 12b is formed at the predetermined position of each of the base portions 121-124. Each via hole 12b is filled with the conducting material 12a. Then, in the layering process, the base portions 121-125 are layered on top of each other in this order to form the layer structure. The base portion 123 incorporates the semiconductor devices Qa and Qb therein. The base portion 124 is located between the base portions 123 and 125 and has the conductive pattern 12c on the near side to the base portion 125. The base portion 125 does not have either the conductive pattern 12c or the via hole 12b filled with the conducting material 12a. Then, in the heat and pressure application process, heat and pressure are applied to the layered structure by using the pressing machine so that the base portions 121-125 can be bonded together into the multilayer board 12. Then, in the heat-dissipator bonding process, the heat dissipator 14 is directly attached on one side (i.e., the first surface defined by the base portion 125) of the multilayer board 12 by thermal-pressure bonding. Thus, in the heat dissipation structure 110 manufactured by the method according to the second embodiment, the base portion 125 serving as an electrically insulation layer can be interposed between the heat dissipator 14 and the semiconductor devices Qa and Qb. Therefore, electrical isolation between the heat dissipator 14 and the semiconductor devices Qa and Qb can be provided by the base portion 125. In addition, since the base portion 125 of the multilayer board 12 is in contact with the heat dissipator 14, the heat dissipation efficiency can be further improved.

### Third Embodiment

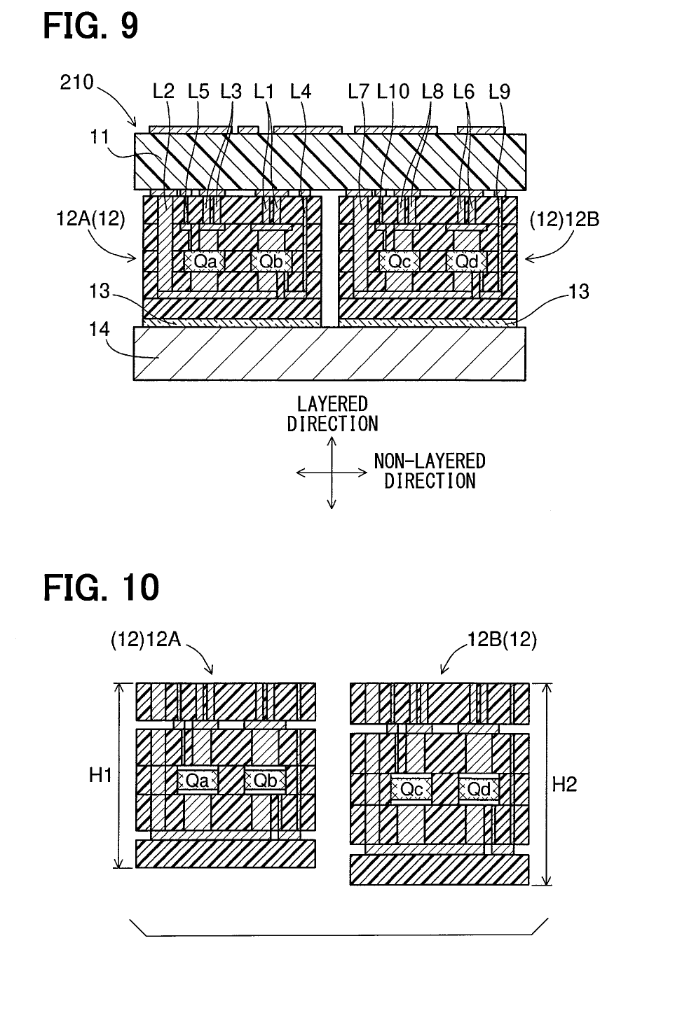

A heat dissipation structure 210 according to a third embodiment of the present disclosure is described below with reference to FIGS. 9-11. A difference between the first embodiment and the third embodiment is that multiple multilayer boards are placed between the circuit board 11 and the heat dissipator 14.

For example, according to the third embodiment, as shown in FIG. 9, the heat dissipation structure 210 includes two multilayer boards 12A and 12B in addition to the circuit board 11, the heat conductor 13, and the heat dissipator 14. Each of the multilayer boards 12A and 12B is structured in the same manner as the multilayer board 12 of the first embodiment. The multilayer boards 12A and 12B are arranged side by side in a non-layered direction perpendicular to the layered direction between the circuit board 11 and the heat dissipator 14.

According to the third embodiment, the semiconductor devices Q1 and Q2 are incorporated in the multilayer board 12A and labeled as “Qa” and “Qb” in FIG. 9, respectively. Further, the semiconductor devices Q3 and Q4 are incorporated in the multilayer board 12B and labeled as “Qc” and “Qd” in FIG. 9, respectively. The semiconductor devices Q1, Q2, Q3, and Q4 are hereinafter sometimes referred to as the “semiconductor devices Qa, Qb, Qc, and Qd”, respectively.

The circuit board 11 and the multilayer boards 12A and 12B form a drive circuit for driving the rotating electrical machine 20. Each of the multilayer boards 12A and 12B provides a part of the drive circuit corresponding to one phase of the rotating electrical machine 20. For example, according to the third embodiment, the multilayer board 12A provides a part (i.e., a part indicated by a broken line in FIG. 2) of the drive circuit corresponding to the U-phase of the rotating electrical machine 20, and the multilayer board 12B provides a part (i.e., a part indicated by a two-dot chain line in FIG. 2) of the drive circuit corresponding to the V-phase of the rotating electrical machine 20. The multilayer board 12A has the interlayer connection conductors L1, L2, L3, L4, and L5, and the multilayer board 12B has interlayer connection conductors L6, L7, L8, L9, and L10.

As shown in FIG. 10, a height H1 of the multilayer board 12A may be different from a height H2 of the multilayer board 12B, for example, due to a difference in the thickness of the base portion caused by a manufacturing tolerance. Likewise, when the number of base portions is different between the multilayer boards 12A and 12B, the height H1 of the multilayer board 12A may be different from the height H2 of the multilayer board 12B. Even when the height H1 of the multilayer board 12A is different from the height H2 of the multilayer board 12B, the heat dissipation structure 210 can be manufactured by almost the same manufacturing method as described in the first embodiment.

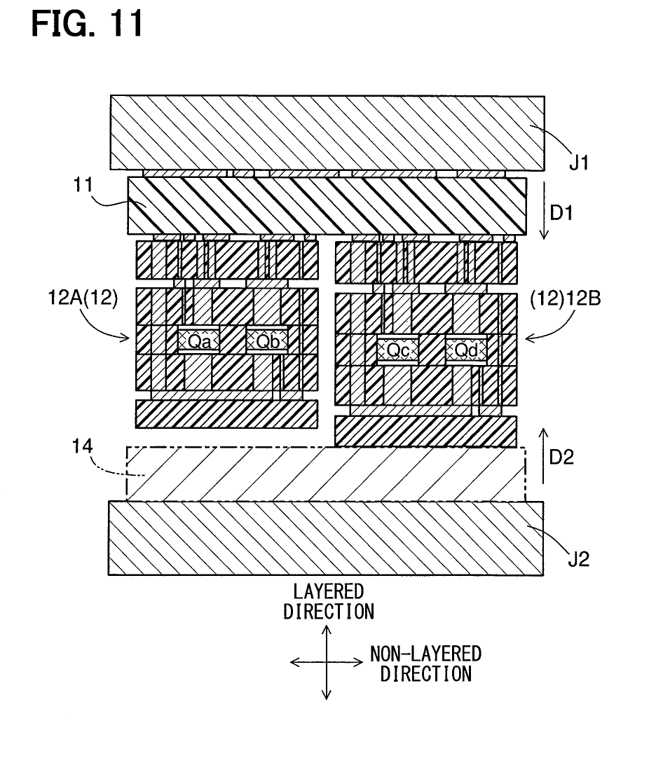

Specifically, in the second procedure of the heat and pressure application process, as shown in FIG. 11, the multilayer boards 12A and 12B are arranged side by side in the non-layered direction between the jigs J1 and J2 of the pressing machine, and then the jigs J1 and J2 are moved in the opposite directions D1 and D2 to apply heat and pressure to the multilayer boards 12A and 12B. As a result, the multilayer boards 12A and 12B are compressed in the layered direction so that the heights H1 and H2 of the multilayer boards 12A and 12B can become equal to each other. In an example of FIG. 11, the multilayer board 12B is more compressed than the multilayer board 12A in the layered direction. Further the base portion 125, serving as an electrically insulating layer, of each of the multilayer boards 12A and 12B becomes flattened. Therefore, the distance between the heat dissipator 14 and the base portion 125 of each of the multilayer boards 12A and 12B (i.e., the thickness of the heat conductor 13) is reduced so that the heat dissipation efficiency can be improved.

Instead of the above second procedure of the heat and pressure application process, the heat-dissipator bonding process as described in the second embodiment can be performed. Specifically, as indicated by a two-dot chain line in FIG. 11, the multilayer boards 12A and 12B are arranged side by side in the non-layered direction between the circuit board 11 and the heat dissipator 14 in the layered direction, and then heat and pressure are applied by using the jigs J1 and J2. In such approach, the heat dissipator 14 is directly bonded to the base portion 125 of each of the multilayer boards 12A and 12B without the heat conductor 13 so that the heat dissipator 14 can be in contact with the base portion 125. Therefore, the heat dissipation efficiency can be further improved.

The third embodiment can have almost the same advantages as described above for the first embodiment or the second embodiment. Further, the third embodiment can have the following advantages.

The multiple multilayer boards 12A and 12B are arranged side by side in the non-layered direction between the circuit board 11 and the heat conductor 13 or the heat dissipator 14. Thus, heat generated in the multilayer boards 12A and 12B is dissipated directly to the heat dissipator 14 or indirectly dissipated to the heat dissipator 14 through the heat conductor 13.

In the heat and pressure application process, after the circuit board 11 is stacked on the multilayer boards 12A and 12B in the layered direction, heat and pressure are applied to the circuit board 11 and the multilayer boards 12A and 12B by using the pressing machine. Thus, the circuit board 11 and the multilayer boards 12A and 12B can be surely connected together.

In the heat and pressure application process, the multilayer boards 12A and 12B are arranged side by side in the non-layered direction, and heat and pressure are applied to the multilayer boards 12A and 12B. In such an approach, even when the heights of the multilayer boards 12A and 12B are different from each other before the heat and pressure application process, the heights of the multilayer boards 12A and 12B becomes substantially equal to each other after the heat and pressure application process. Therefore, the distance between the heat dissipator 14 and the base portion 125 of each of the multilayer boards 12A and 12B (i.e., the thickness of the heat conductor 13) is reduced so that the heat dissipation efficiency can be improved.

In the heat-dissipator bonding process, the multilayer boards 12A and 12B are arranged side by side in the non-layered direction between the circuit board 11 and the heat dissipator 14 in the layered direction, and then heat and pressure are applied by using the pressing machine. In such approach, the heat dissipator 14 is directly bonded to the base portion 125 of each of the multilayer boards 12A and 12B without the heat conductor 13 so that the heat dissipator 14 can be in contact with the base portion 125. Therefore, the heat dissipation efficiency can be further improved.

(Modifications)

While the present disclosure has been described with reference to embodiments thereof, it is to be understood that the disclosure is not limited to the embodiments. The present disclosure is intended to cover various modifications and equivalent arrangements within the spirit and scope of the present disclosure.

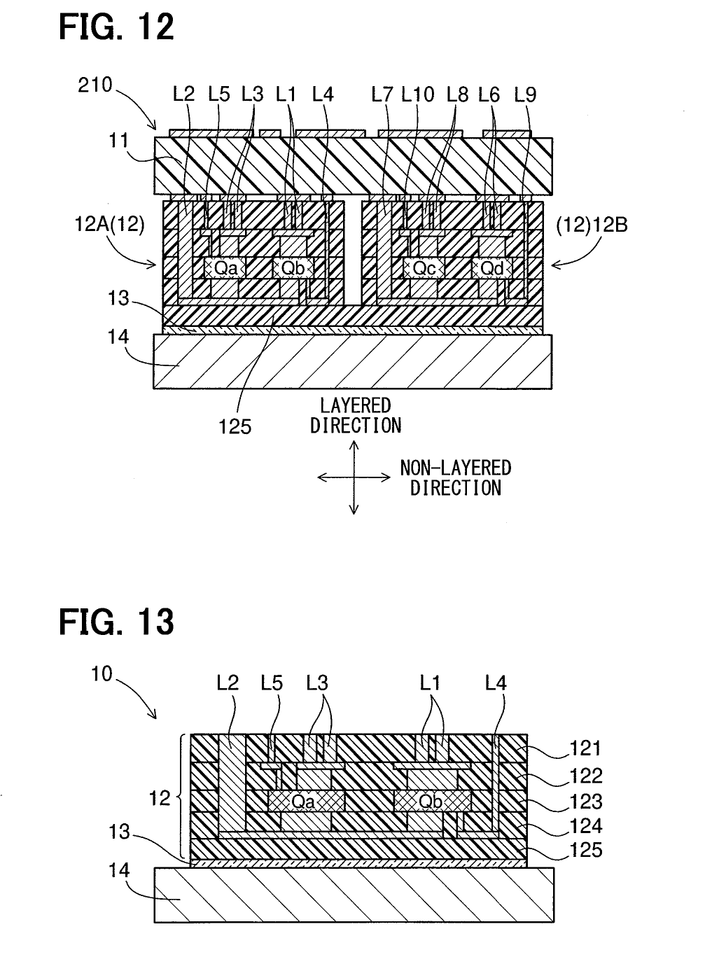

FIG. 12 shows a modification of the third embodiment. As shown in FIG. 12, the heat dissipation structure 210 can have a common base portion 125 shared between multiple multilayer boards. Obviously, the heat dissipation structure 210 shown in FIG. 12 can be manufactured by almost the same method as described in the third embodiment. Specifically, the layered process and the first procedure of the heat and pressure application process are performed without the base portion 125. Then, in the second procedure of the heat and pressure application process, the multilayer boards 12A and 12B except the base portion 125 are placed on the common base portion 125 and arranged side by side in the non-layered direction between the jigs J1 and J2. Then, the jigs J1 and J2 are moved to apply heat and pressure. In such an approach, the number of manufacturing processes can be reduced compared to when each of the multilayer boards 12A and 12B has an individual base portion 125. In FIG. 12, the heat conductor 13 is interposed between the common base portion 125 and the heat dissipator 14. Alternatively, the heat conductor 13 can be removed as described in the second embodiment.

FIG. 13 shows a modification of the first embodiment. As shown in FIG. 13, the heat dissipation structure 10 can have no circuit board 11. Obviously, the heat dissipation structure 10 shown in FIG. 13 can be manufactured by almost the same method as described in the first embodiment. In FIG. 13, the heat conductor 13 is interposed between the base portion 125 and the heat dissipator 14. Alternatively, the heat conductor 13 can be removed as described in the second embodiment.

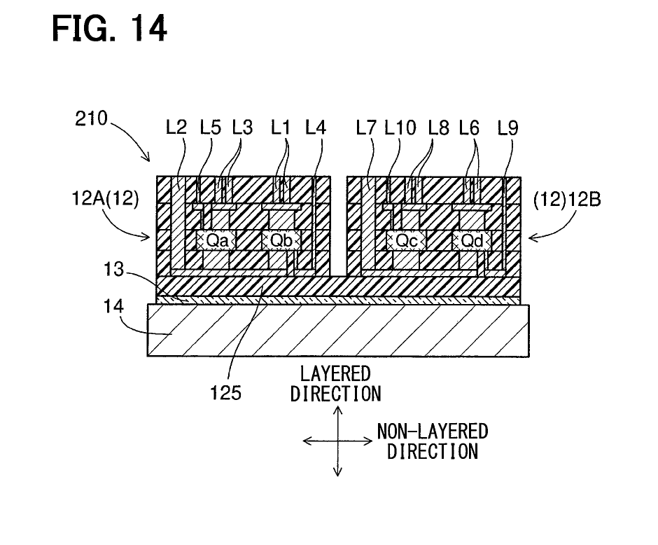

FIG. 14 shows a modification of the third embodiment. As shown in FIG. 14, the heat dissipation structure 210 can have no circuit board 11. Obviously, the heat dissipation structure 210 shown in FIG. 14 can be manufactured by almost the same method as described in the third embodiment. In FIG. 14, the heat conductor 13 is interposed between the common base portion 125 and the heat dissipator 14. Alternatively, the heat conductor 13 can be removed as described in the second embodiment.

In the third embodiment, each of the multilayer boards 12A and 12B of the heat dissipation structure 210 has the same structure. Alternatively, each of the multilayer boards 12A and 12B can have a different structure.

In the third embodiment, the heat dissipation structure 210 includes two multilayer boards 12A and 12B. Alternatively, the heat dissipation structure 210 can include three or more multilayer boards regardless of whether each multilayer board has the same or different structure.

The number of the layered base portions of the multilayer board is not limited to five. In practice, the upper limit for the number of the layered base portions of the multilayer board may be several tens of layers (e.g., fifty).

The electronic device incorporated in the multilayer board 12 is not limited to the switching device Qa-Qd. In addition to or instead of the switching device, another type of electronic device can be incorporated in the multilayer board 12. Examples of the electronic device incorporated in the multilayer board 12 can include a diode, a semiconductor relay, an IC, a resistor, a capacitor, and a coil (i.e., inductor or reactor). Also, the number of electronic devices incorporated in the multilayer board 12 is not limited to a specific number.

A cooler and/or a heater can be used instead of or in addition to the heat dissipator 14. In such an approach, the temperature of the electronic device incorporated in the multilayer board 12 can be directly controlled so that the electronic device can be kept at temperatures suitable for the operation of the electronic device. For example, the cooler can include liquid coolant (e.g., water or oil) and a pipe through which the liquid coolant flows. It is preferable that the heater be used in cold climate regions.

A load controlled by the drive circuit provided by the multilayer board 12 is not limited to the three-phase rotating electrical machine 20. For example, the load can be a single-phase or a six-phase rotating electrical machine. Also, the load can be a load other than a rotating electrical machine.

The first procedure of the heat and pressure application process and the heat-dissipator bonding process can be performed at the same time. For example, the heat dissipator 14 is placed on the base portion 125 of the layered structure, and then heat and pressure are applied to the layered structure and the heat dissipator 14 by using the jigs J1 and J2. In such an approach, while the layered structure is bonded together into the multilayer board 12, the base portion 125 is bonded to the heat dissipator 14 so that the multilayer board 12 and the heat dissipator 14 can be joined together. Thus, the number of manufacturing processes can be reduced. In this case, the circuit board 11 can be placed on the base portion 121 of the layered structure, and/or the heat conductor 13 can be placed between the heat dissipator 14 and the base portion 125 of the layered structure.

What is claimed is:

1. A heat dissipation structure comprising:
a multilayer board having a first surface and a second surface opposite to the first surface in a layered direction; and
a heat dissipator located on the first surface side of the multilayer board, wherein
the multilayer board includes an electronic device, an electrically insulating layer, and a plurality of base portions made of electrically insulating material,
the electronic device is incorporated in the plurality of base portions,
the insulating layer and the plurality of base portions are layered together to form the multilayer board in such a manner that a first one of the plurality of base portions defines the first surface of the multilayer board and that the insulating layer defines the second surface of the multilayer board,
each of the plurality of base portions has an interlayer connection conductor extending therethrough in the layered direction, the interlayer connection conductor being made of electrically conducting material and connected to the electronic device,
at least one of the plurality of base portions has a conductive pattern connected to the interlayer connection conductor, and
the insulating layer has no interlayer connection conductor and is located between the electronic device and the heat dissipator in the layered direction.

2. The heat dissipation structure according to claim 1, wherein
the at least one of the plurality of base portions is located adjacent to the insulating layer and has the conductive pattern at an interface with the insulating layer.

3. The heat dissipation structure according to claim 1, further comprising:
a circuit board located on the second surface side of the multilayer board.

4. The heat dissipation structure according to claim 1, wherein
the electronic device is accommodated in an accommodation hole defined by at least one of the plurality of base portions.

5. The heat dissipation structure according to claim 1, wherein
the electronic device is incorporated in a second one of the plurality of base portions, and
a thickness of the electronic device is substantially equal to a thickness of the second one of the plurality of base portions in the layered direction.

6. The heat dissipation structure according to claim 1, wherein
the heat dissipator is in contact with the insulating layer of the multilayer board.

7. The heat dissipation structure according to claim 1, further comprising:
a heat conductor located between the heat dissipator and the insulating layer of the multilayer board.

8. The heat dissipation structure according to claim 1, further comprising:
a plurality of multilayer boards including the multilayer board, wherein
the plurality of multilayer boards are arranged side by side in a non-layered direction perpendicular to the layered direction.

9. The heat dissipation structure according to claim 8, wherein
the insulating layer of a first one of the plurality of multilayer boards is joined to the insulating layer of a second one of the plurality of multilayer boards.

10. A method of manufacturing a heat dissipation structure for a multilayer board, the method comprising:
a step of preparing an electrically insulating layer and a plurality of base portions made of electrically insulating material, the preparing step including forming a via hole in each of the plurality of base portions and filling the via hole with electrically conducting material, the preparing step further including forming a conductive pattern on at least one of the plurality of base portions;
a step of incorporating an electronic device in the plurality of base portions;
a step of layering the insulating layer and the plurality of base portions together in a layered direction to form a layered structure such that an outermost surface of the layered structure is defined by the insulating layer and such that the at least one of the plurality of base portions is located between the electronic device and the insulating layer;
a step of applying heat and pressure to the layered structure by using a pressing machine so that the insulating layer and the plurality of base portions are bonded together into the multilayer board; and
a step of mounting a heat dissipator on the insulating layer side of the multilayer board.

11. The method according to claim 10, wherein
the applying step includes placing a circuit board on one side of the multilayer board opposite to the insulating layer side and applying heat and pressure to the circuit board and the multilayer board.

12. The method according to claim 11, wherein
the mounting step is performed after the circuit board is placed.

13. The method according to claim 10, wherein
the mounting step includes directly attaching the heat dissipator to the insulating layer of the multilayer board by thermal-pressure bonding.

14. The method according to claim 10, wherein
the mounting step includes placing a heat conductor between the heat dissipator and the insulating layer of the multilayer board.

15. The method according to claim 10, further comprising:
a step of preparing a plurality of multilayer boards including the multilayer board, wherein
the mounting step includes arranging the plurality of multilayer boards side by side in a non-layered direction perpendicular to the layered direction and mounting the heat dissipator on the insulating layer side of each of the plurality of multilayer boards.

16. The method according to claim 10, wherein
the preparing step includes preparing a plurality of sets, each set having the plurality of base portions,
the incorporating step includes incorporating the electronic device in each set, and
the layering step includes layering the insulating layer and the plurality of sets together in the layered direction to form the layered structure.

17. A method of manufacturing a heat dissipation structure for a multilayer board, the method comprising:
a step of preparing an electrically insulating layer and a plurality of base portions made of electrically insulating material, the preparing step including forming a via hole in each of the plurality of base portions and filling the via hole with electrically conducting material, the preparing step further including forming a conductive pattern on at least one of the plurality of base portions;
a step of incorporating an electronic device in the plurality of base portions;
a step of layering the insulating layer and the plurality of base portions together in a layered direction to form a layered structure such that an outermost surface of the layered structure is defined by the insulating layer and such that the at least one of the plurality of base portions is located between the electronic device and the insulating layer;
a step of arranging the layered structure between a circuit board and a heat dissipator in the layered direction in such a manner that the heat dissipator is located on the insulating layer side of the layered structure; and
a step of applying heat and pressure to the layered structure through the circuit board and the heat dissipator by using a pressing machine.

18. The method according to claim 17, wherein the arranging step includes placing a heat conductor between the heat dissipator and the insulating layer of the layered structure.

19. The method according to claim 17, further comprising:
a step of preparing a plurality of layered structures including the layered structure, wherein
the arranging step includes arranging the plurality of layered structures side by side in a non-layered direction perpendicular to the layered direction between the circuit board and the heat dissipator, and
the applying step includes applying the heat and pressure to the plurality of layered structures through the circuit board and the heat dissipator by using the pressing machine.

20. The method according to claim 17, wherein
the preparing step includes preparing a plurality of sets, each set having the plurality of base portions,
the incorporating step includes incorporating the electronic device in each set, and
the layering step includes layering the insulating layer and the plurality of sets together in the layered direction to form the layered structure.
